(19) United States
(12) Patent Application Publication
(10) Pub. No.: US 2026/0247558 A1
(43) Pub. Date: Aug. 20, 2026

(54) ELECTRONIC APPARATUS

(71) Applicant: AISIN CORPORATION, Kariya (JP)

(72) Inventor: Masaki TAKAYAMA, Kariya-shi (JP)

(73) Assignee: AISIN CORPORATION, Kariya (JP)

(21) Appl. No.: 19/542,016

(22) Filed: Feb. 17, 2026

(30) Foreign Application Priority Data
Feb. 19, 2025 (JP) 2025-025347

(51) Int. Cl. H05K 7/14; H05K 5/02

(52) U.S. Cl. CPC H05K 7/1427; H05K 5/0217

(57) ABSTRACT

An electronic apparatus includes: a substrate having a mounting surface on which an electronic component is disposed; and a case disposed to face the mounting surface and including a partition portion configured to allow the electronic component to be accommodated. The substrate has a through hole. The partition portion includes an attachment portion erected to a side of the substrate at a position overlapping the through hole as viewed in a direction orthogonal to the substrate. The partition portion is filled with a resin.

### CROSS REFERENCE TO RELATED APPLICATIONS

This application is based on and claims priority under 35 U.S.C. §119 to Japanese Patent Application 2025-025347, filed on February 19, 2025, the entire content of which is incorporated herein by reference.

### TECHNICAL FIELD

This disclosure relates to an electronic apparatus.

### BACKGROUND DISCUSSION

JP 2007-182962A (Reference 1) discloses an electromagnetic actuator (an example of an electronic apparatus). This electromagnetic actuator includes a bobbin and a stator, and positioning of the bobbin and the stator is performed by fitting two positioning holes (an example of a positioning hole) provided in a stator flange (an example of a substrate) and two positioning protrusions provided in a bobbin flange. The stator flange is provided with a resin passage hole (an example of a resin injection hole) for injecting a molding resin separately from the positioning holes. The positioning hole has a circular hole shape, the positioning protrusion has an oval shape matching a diameter portion of the circular hole, and a resin passage gap is formed therebetween. Accordingly, in the electromagnetic actuator, the total number of the positioning holes and the resin passage hole can be reduced.

In the electronic apparatus in Reference 1, a part of the positioning holes is also used as a hole for resin injection. However, since the positioning protrusion is fitted into the positioning hole, it is necessary to increase a size of the positioning hole itself in order to easily inject the resin from the resin passage gap between the positioning hole and the positioning protrusion. However, when the positioning hole is enlarged, it is necessary to enlarge an outer shape of the substrate. In addition, in the electronic apparatus, when the positioning hole is formed in the substrate, an area where pattern printing cannot be performed on the substrate increases as the size of the positioning hole increases, and thus it is necessary to take measures such as increasing the outer shape of the substrate or increasing the number of layers of the substrate. Therefore, there is room for improvement in the electronic apparatus including the positioning holes and the resin injection hole provided in the substrate.

A need thus exists for an electronic apparatus which is not susceptible to the drawback mentioned above.

### SUMMARY

According to an aspect of this disclosure, an electronic apparatus includes: a substrate having a mounting surface on which an electronic component is disposed; and a case disposed to face the mounting surface and including a partition portion configured to allow the electronic component to be accommodated, in which the substrate has a through hole, the partition portion includes an attachment portion erected to a side of the substrate at a position overlapping the through hole as viewed in a direction orthogonal to the substrate, and the partition portion is filled with a resin.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is a perspective view of an electronic apparatus in which a substrate is positioned in a case;

FIG. 2 is an exploded perspective view of the electronic apparatus;

FIG. 3 is an enlarged perspective view of a main part of the case;

FIG. 4 is a plan view of a main part of the electronic apparatus;

FIG. 5 is a partially enlarged perspective view of a positioning mechanism disposed at a corner of the substrate;

FIG. 6 is a partial perspective cross-sectional view of the electronic apparatus with a positioning jig inserted into the substrate;

FIG. 7 is a partial cross-sectional view of the electronic apparatus with the positioning jig inserted into the substrate;

FIG. 8 is a perspective view of an end portion of the positioning jig;

FIG. 9 is a diagram showing a planar shape (protrusion shape) of an attachment portion and a planar shape (jig shape) of the end portion of the positioning jig facing the attachment portion;

FIG. 10 is a diagram showing a planar shape (protrusion shape) of an attachment portion and a planar shape (jig shape) of an end portion of a positioning jig facing the attachment portion according to another embodiment;

FIG. 11 is a diagram showing a planar shape (protrusion shape) of an attachment portion and a planar shape (jig shape) of an end portion of a positioning jig facing the attachment portion according to another embodiment; and

FIG. 12 is a diagram showing a planar shape (protrusion shape) of an attachment portion and a planar shape (jig shape) of an end portion of a positioning jig facing the attachment portion according to another embodiment.

### DETAILED DESCRIPTION

Hereinafter, embodiments of an electronic apparatus 1 disclosed here will be described in detail with reference to the drawings. The embodiment to be described below is an example for describing this disclosure, and this disclosure is not limited to these embodiments alone. Therefore, this disclosure can be implemented in various forms without departing from the gist of this disclosure.

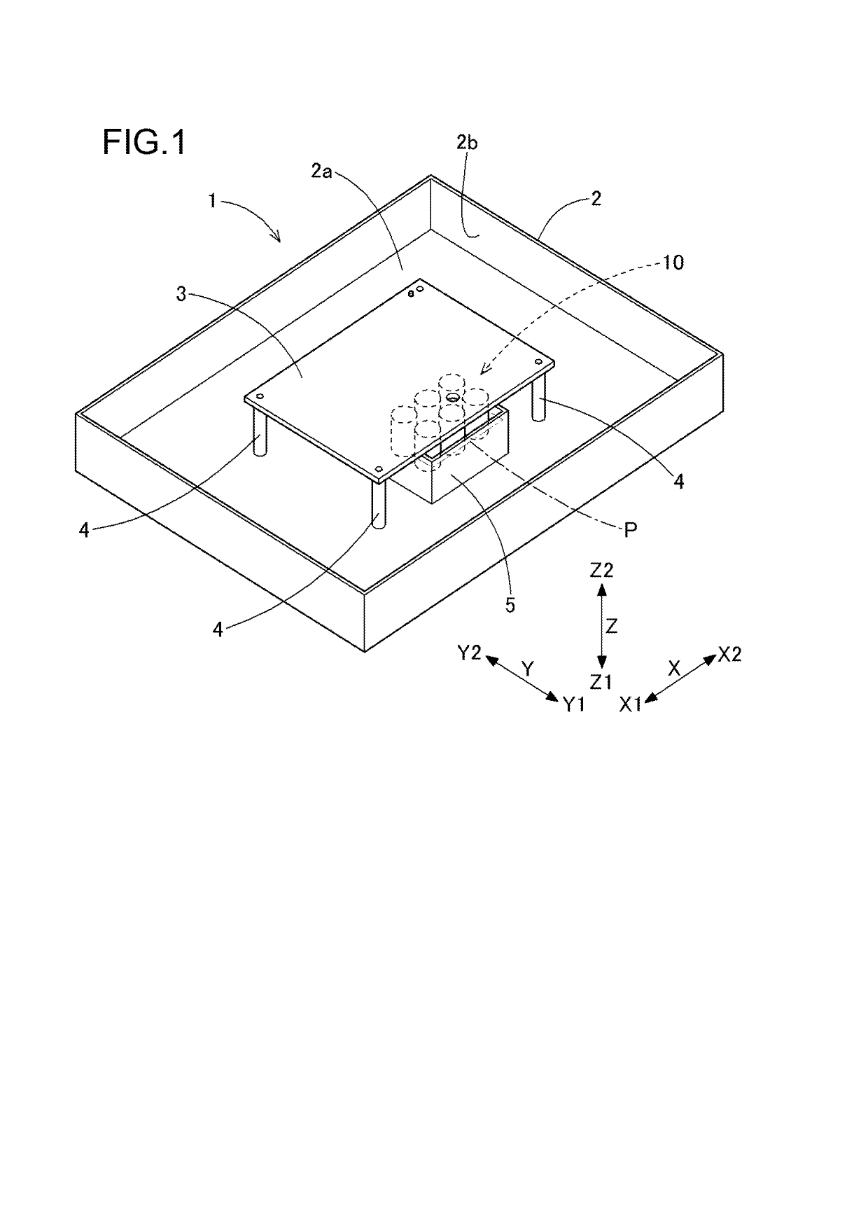

As shown in FIG. 1, the electronic apparatus 1 is provided with a substrate 3 having a plurality of electronic components 10 mounted on a mounting surface 3a (lower surface) in a case 2 having a rectangular shape in a plan view. Although details will be described later, an uncured resin P such as a urethane resin is poured into a partition portion 5 of the case 2 in a state where the plurality of electronic components 10 are accommodated, and the resin P is cured. That is, in the electronic apparatus 1, the partition portion 5 is filled with the resin P. Regarding the filling the partition portion 5 with the resin P, all the electronic components 10 may be filled with the resin P, or only a part of the electronic components 10 may be filled with the resin P. In the following description, a direction in which two facing sides of four sides constituting the rectangle of the case 2 extend is defined as an X direction, and a direction orthogonal to the X direction is defined as a Y direction (a direction in which the other two facing sides extend). A direction orthogonal to both the X direction and the Y direction will be described as a Z direction. In the drawings, one side of the X direction is referred to as an X1 side, and the other side is referred to as an X2 side. One side of the Y direction is referred to as an Y1 side, and the other side is referred to as an Y2 side. An upper side (one side) of the Z direction is referred to as a Z2 side, and a lower side (the other side) is referred to as a Z1 side.

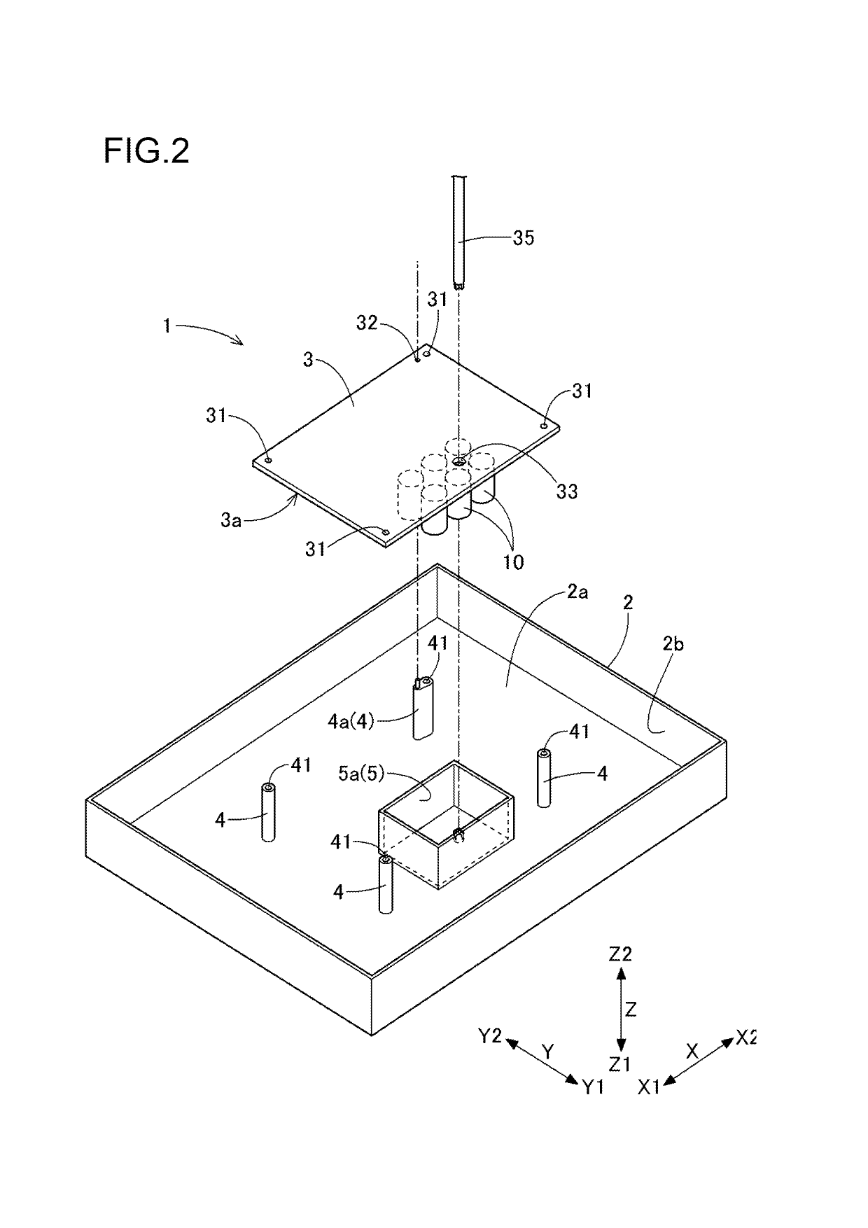

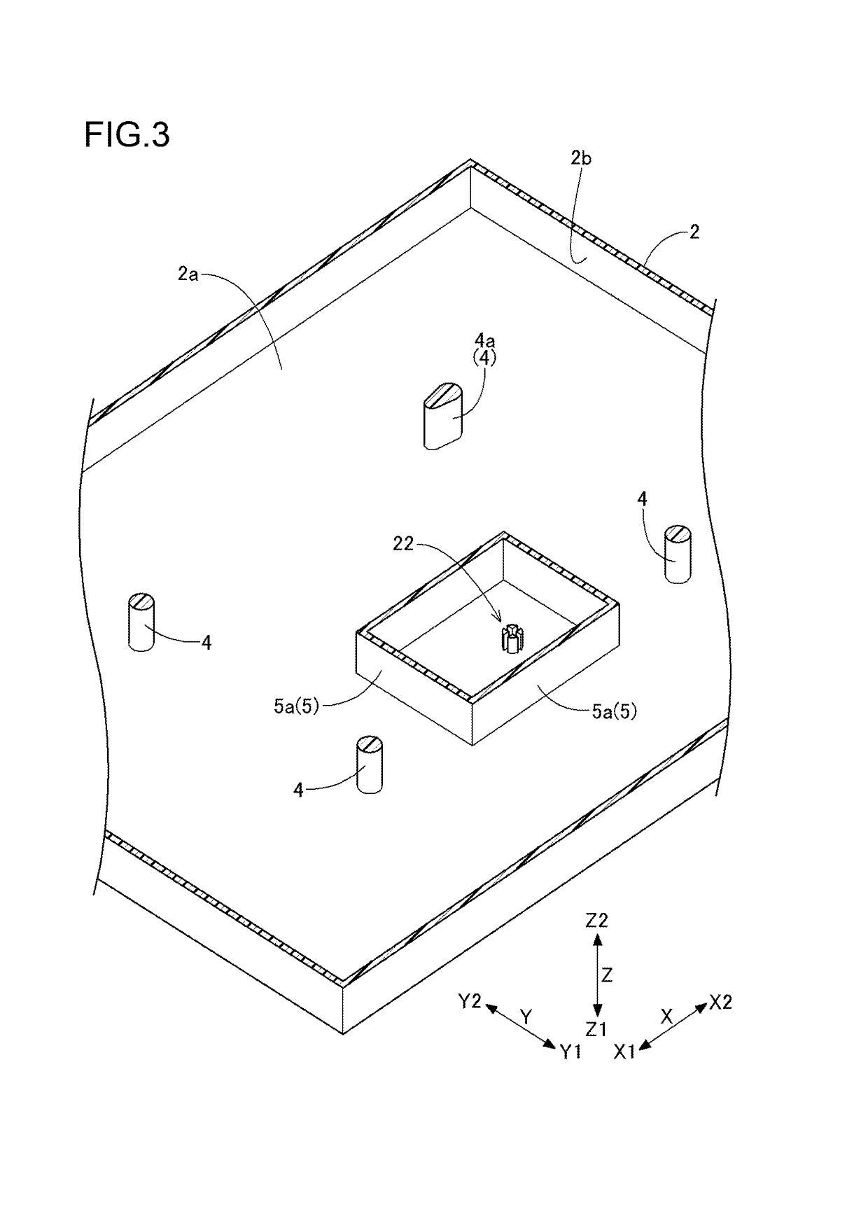

As shown in FIG. 2, in order to fix the substrate 3, the case 2 is formed with four fixing portions 4 erected on a bottom surface 2a of the case 2. That is, the fixing portions 4 extend upward (Z2 side) from the bottom surface 2a of the case 2. In the present embodiment, the fixing portions 4 are disposed at positions corresponding to vertices of a rectangle in a plan view, respectively. In the case 2, the partition portion 5 that is disposed to face the mounting surface 3a of the substrate 3 and can accommodate the plurality of electronic components 10 is provided inside the four fixing portions 4. The partition portion 5 is formed in a rectangular tubular shape by being surrounded by four wall portions 5a erected on the bottom surface 2a of the case 2. The case 2 can be manufactured by, for example, injection molding.

Each of the four fixing portions 4 is formed in a rod shape, and a recessed portion 41 for fixing a bolt is provided on an upper surface (surface on the Z2 side). As shown in FIG. 5, one fixing portion 4a of the four fixing portions 4 is provided with a positioning pin 42 in addition to the recessed portion 41.

The substrate 3 is formed in a rectangular shape, and fixing holes 31 are provided at four corners in the plan view, respectively. The substrate 3 is provided with a positioning hole portion 32 in addition to the fixing holes 31 at a position corresponding to the fixing portion 4a.

The plurality of electronic components 10 are provided on the mounting surface 3a of the substrate 3. In the present embodiment, as shown in FIGS. 1, 2, and 4, six columnar electronic components 10 are provided on the mounting surface 3a of the substrate 3. The six electronic components 10 are disposed on the Y1 side in the Y direction and at a center in the X direction in the substrate 3, and are arranged in two rows in the Y direction with three electronic components arranged along the X direction in one row. A shape of the electronic component 10 is not limited to the columnar shape and may be another shape, the number of electronic components 10 mounted on the substrate 3 is not limited to two or more and may be one, and similarly, the number of electronic components 10 accommodated in the partition portion 5 is not limited to two or more and may be one.

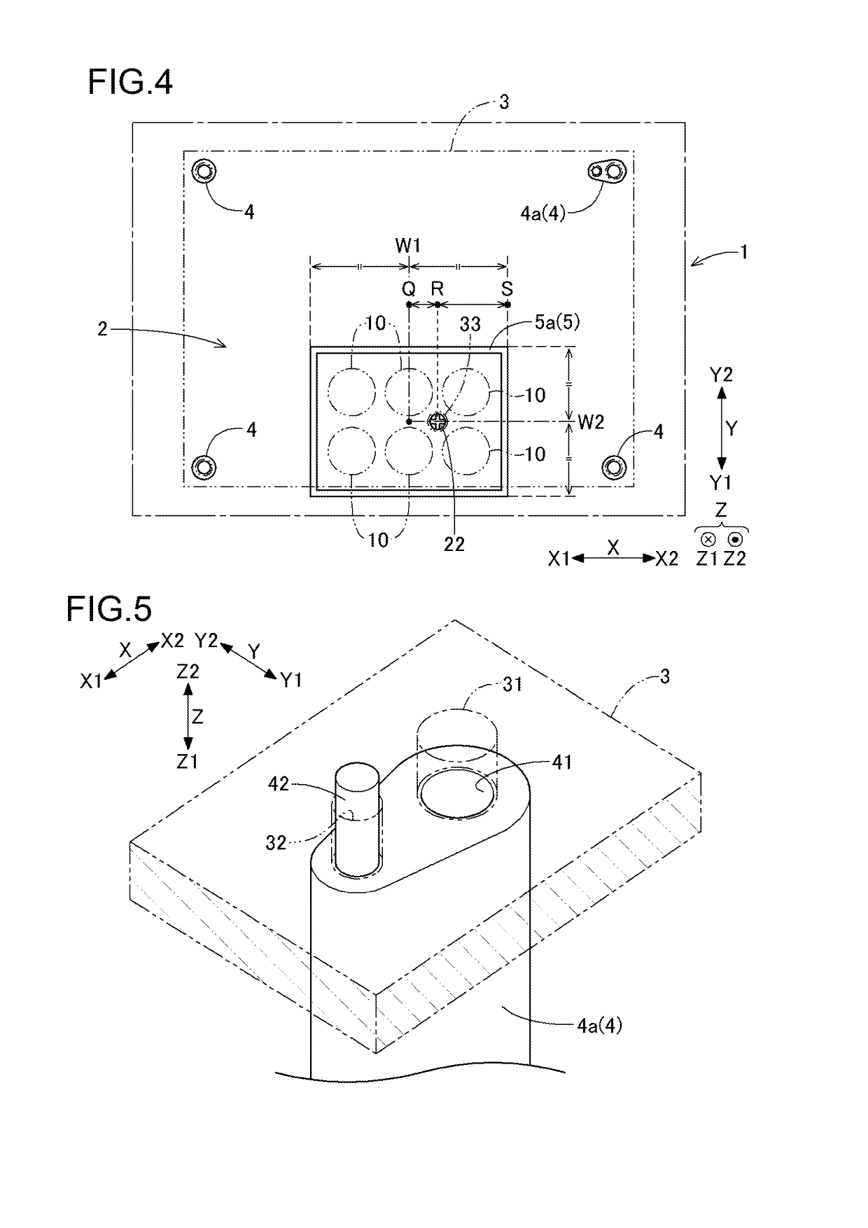

As shown in FIG. 4, the substrate 3 has a through hole 33 at a position facing the partition portion 5. The through hole 33 is a hole that can be used for injecting the resin P into the partition portion 5. The through hole 33 is provided so as to be located closer to a center of the partition portion 5 in any of a width direction W1 and a width direction W2 as viewed in the Z direction orthogonal to the substrate 3. Specifically, the width direction W1 is a width of the partition portion 5 in the X direction, and the width direction W2 is a width of the partition portion 5 in the Y direction. The through hole 33 is located at a point R on the X2 side of a center Q in the width direction W1, and the point R is closer to the center Q in the width direction W1 than an end point S on the X2 side in the width direction W1. The through hole 33 is located at the center in the width direction W2. From this, it can be understood that the through hole 33 is located closer to the center of the partition portion 5 in any of the width directions W1 and W2 as viewed in the Z direction orthogonal to the substrate 3. Note that "located closer to the center of the partition portion 5 in any of the width directions W1 and W2 as viewed in the Z direction" means that the through hole 33 is located in a region where a region of 1/4 of an entire length from the center toward both end sides in the width direction W1 and a region of 1/4 of the entire length from the center toward both end sides in the width direction W2 overlap each other.

The partition portion 5 is provided at a position overlapping the through hole 33 as viewed in the Z direction orthogonal to the substrate 3, and includes an attachment portion 22 to which a positioning jig 35 that can be inserted from the through hole 33 is detachably attached. The attachment portion 22 is provided to protrude from the bottom surface 2a of the case 2 toward the substrate 3. That is, the attachment portion 22 is provided so as to protrude from the bottom surface 2a of the case 2 toward the Z2 side.

The attachment portion 22 includes a holding portion 23 that comes into contact with an end portion 35a of the positioning jig 35 to be described later and holds the positioning jig 35, an inner space portion 24 that is provided on an inner side of the holding portion 23 and opens to a side facing the substrate 3, and a communication portion 25 that communicates with an outer side from the inner space portion 24 in a direction along the substrate 3.

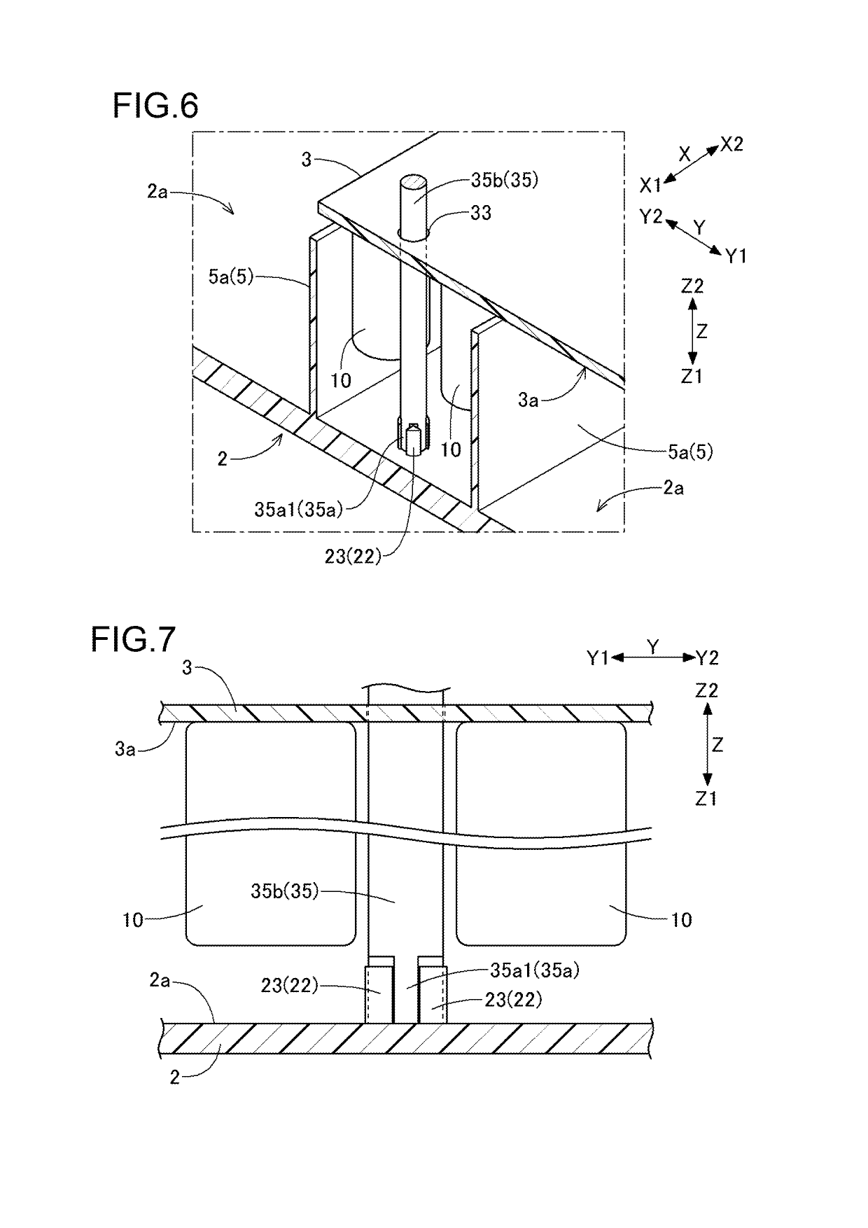

As shown in FIGS. 6 to 9, the holding portion 23 is constituted by four columnar bodies 23a radially distributed and disposed on the bottom surface 2a of the case 2. The four columnar bodies 23a are formed by dividing a cylinder into four portions as viewed in the Z direction. The inner space portion 24 is provided on the inner side of the four columnar bodies 23a. As shown in FIG. 9, the inner space portion 24 of the present embodiment is a rectangular portion connecting center points of the four fan-shaped columnar bodies 23a. The communication portion 25 is linearly formed with a predetermined width from the inner space portion 24 toward an outer side of the holding portion 23. As shown in FIG. 9, the communication portion 25 of the present embodiment is a portion formed between the columnar bodies 23a adjacent to each other in a circumferential direction, and is formed so as to communicate with an outer side of the attachment portion 22 at four locations of the inner space portion 24 as viewed in the Z direction.

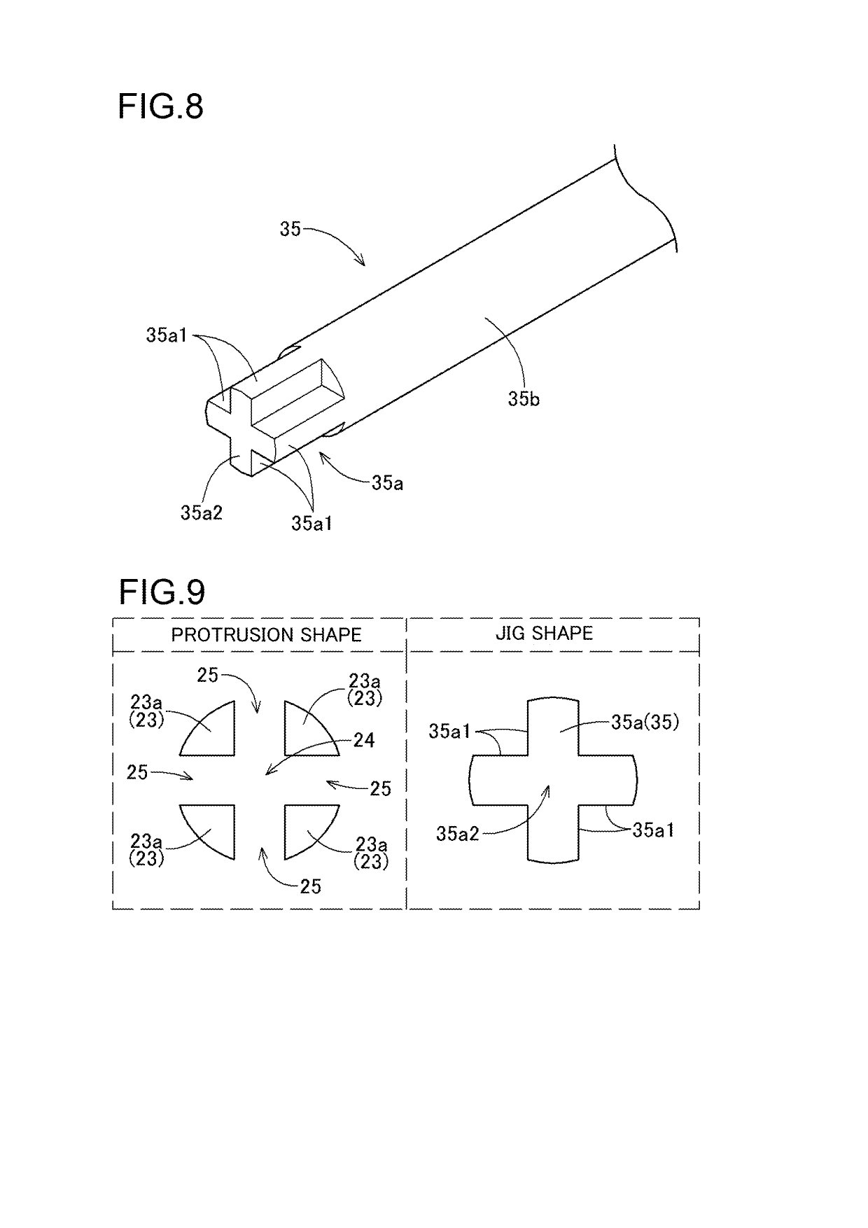

The entire positioning jig 35 is formed in a rod shape. As shown in FIGS. 8 and 9, a main body portion 35b of the positioning jig 35 has a columnar shape, and the end portion 35a on a side facing the attachment portion 22 that is continuous with the main body portion 35b is formed in a cross shape in a cross section.

Hereinafter, a method of assembling the substrate 3 to the case 2 will be described.

Positioning of the substrate 3 with respect to the case 2 is performed by fitting the positioning hole portion 32 and the positioning pin 42 of the fixing portion 4a and coupling the positioning jig 35 inserted from the through hole 33 and the attachment portion 22. Specifically, after the positioning pin 42 of the fixing portion 4a is inserted into the positioning hole portion 32, a position of the substrate 3 is adjusted such that the through hole 33 and the attachment portion 22 overlap each other as viewed in the Z direction. Thereafter, the positioning jig 35 is inserted from the through hole 33 toward the bottom surface 2a of the case 2, and the end portion 35a of the positioning jig 35 is attached to the attachment portion 22. In this manner, the substrate 3 is positioned at two locations with respect to the case 2, and the positioning is completed. In this manner, the through hole 33 functions as a positioning hole.

In a state where the positioning of the substrate 3 with respect to the case 2 is completed, fixing members (not shown) such as a bolt are inserted into the fixing portions 4 and the fixing holes 31. Accordingly, the substrate 3 is fixed to the case 2.

Thereafter, the positioning jig 35 is detached from the attachment portion 22 while being moved toward an upper side of the substrate 3, and is pulled out of the through hole 33. Thereafter, the resin P such as a potting material is injected into the partition portion 5 from the through hole 33. By pulling out the positioning jig 35 from the through hole 33 of the substrate 3, an entire space between the through hole 33 and the attachment portion 22 becomes hollow, and thus the resin P can be easily injected into the partition portion 5 from the through hole 33. In this manner, the through hole 33 also functions as a hole for injecting the resin P into the partition portion 5.

In the present embodiment, since the attachment portion 22 is erected toward a side of the substrate 3, a volume in the partition portion 5 can be reduced by a volume of the attachment portion 22, and a required injection amount of the resin P into the partition portion 5 can be reduced. A dimension of the attachment portion 22 in the Z direction is preferably smaller than or approximately equal to a distance between the electronic components 10 and the bottom surface 2a of the case 2.

Thereafter, the injected resin P is cured to complete the electronic apparatus 1 in which the partition portion 5 in which the electronic components 10 are accommodated is filled with the resin P.

### Other Embodiments

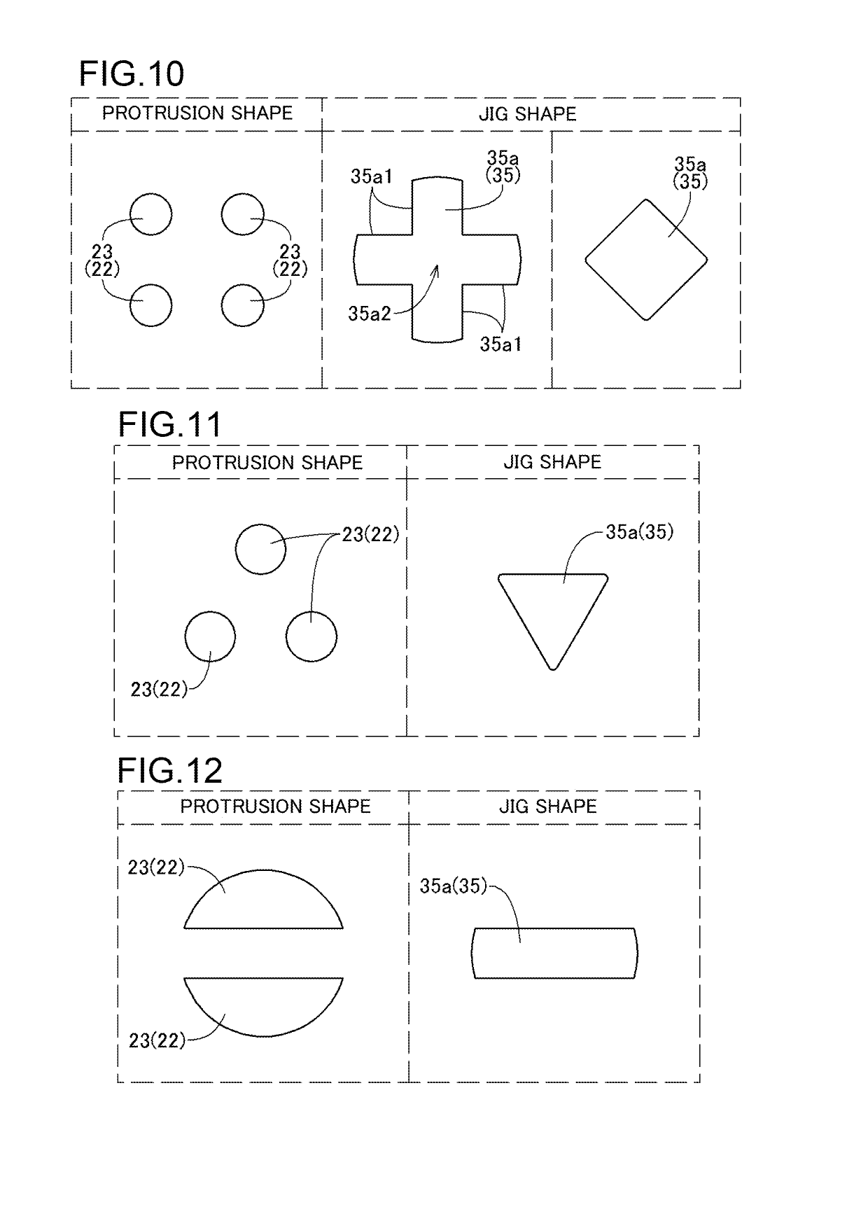

As shown in FIG. 10, in the electronic apparatus 1, the attachment portion 22 may have a configuration in which the holding portion 23 is constituted by four cylindrical bodies distributed and disposed at four corners of a rectangle. In this case, the end portion 35a of the positioning jig 35 may be formed in, for example, a cross shape in a plan view, or may be formed in a square shape in the plan view.

As shown in FIG. 11, in the electronic apparatus 1, the attachment portion 22 may have a configuration in which the holding portion 23 is constituted by three cylindrical bodies distributed and disposed at vertices of a triangle in a plan view. In this case, the end portion 35a of the positioning jig 35 may be formed in, for example, a triangular shape in the plan view.

As shown in FIG. 12, in the electronic apparatus 1, the attachment portion 22 may have a configuration in which the holding portion 23 is constituted by two semicircular columnar bodies disposed apart from each other such that diameter portions thereof face each other. In this case, the end portion 35a of the positioning jig 35 may be formed in, for example, a rectangular shape in plan view.

In the above embodiment, the substrate 3 is positioned with respect to the case 2 by using the positioning hole portion 32 and the through hole 33 provided in the substrate 3. Here, the positioning hole portion 32 is a through hole for the positioning pin 42. That is, in the above embodiment, the substrate 3 has a plurality of through holes, and one through hole 33 thereof is disposed to overlap the attachment portion 22 in the Z direction. However, the number of through holes provided in the substrate 3 does not need to be plural, and may be one. In this case, for example, a shape for positioning an outer edge of the substrate 3 may be provided in the case 2 without providing the positioning hole portion 32 in the substrate 3.

In the above embodiment, an aspect in which one through hole 33 is disposed to overlap the attachment portion 22 as viewed in the Z direction is described, but this disclosure is not limited to such an aspect. In the electronic apparatus 1, a plurality of attachment portions 22 may be provided in one partition portion 5, and the through holes 33 may be disposed in the substrate 3 so as to overlap the respective attachment portions 22. For example, two attachment portions 22 may be provided in one partition portion 5, the through hole 33 may be formed so as to overlap one attachment portion 22, and another through hole 33 may be formed so as to overlap the other attachment portion 22. In this manner, a filling speed of the resin P injected from the through hole 33 into the partition portion 5 can be increased, a hole dedicated to positioning becomes unnecessary, and the substrate 3 can be downsized while securing a necessary area for pattern printing. In addition, the electronic apparatus 1 may include a plurality of partition portions 5, one or a plurality of attachment portions 22 may be provided in each partition portion 5, and the through holes 33 may be disposed in the substrate 3 so as to overlap the respective attachment portions 22. Even in this case, the hole dedicated to positioning becomes unnecessary, and the substrate 3 can be downsized while securing the necessary area for pattern printing.

### Overview of Above Embodiments

Hereinafter, in the above embodiments, the following configurations are conceivable.

<1> One aspect of an electronic apparatus (1) includes: a substrate (3) having a mounting surface (3a) on which an electronic component (10) is disposed; and a case (2) disposed to face the mounting surface (3a) and including a partition portion (5) configured to allow the electronic component (10) to be accommodated, in which the substrate (3) has a through hole (33) through which a resin can be injected into the partition portion (5), the partition portion (5) includes an attachment portion (22) erected to a side of the substrate (3) at a position overlapping the through hole (33) as viewed in a direction (Z direction) orthogonal to the substrate (3), and the partition portion (5) is filled with a resin (P).

According to the present embodiment, in the electronic apparatus (1), the substrate (3) can be positioned with respect to the case (2) by inserting a positioning jig (35) from the through hole (33) provided in the substrate (3) and attaching the positioning jig (35) to the attachment portion (22) provided in the case (2). Further, in the electronic apparatus (1), by removing the positioning jig (35) from the attachment portion (22) and detaching the positioning jig (35) from the through hole (33) to an outer side of the electronic apparatus (1), the partition portion (5) can be efficiently filled with the resin (P) such as a potting material from the through hole (33). As described above, at the time of manufacturing the electronic apparatus (1), the positioning of the substrate (3) and the injection of the resin (P) into the partition portion (5) can be individually performed using the through hole (33) provided in the substrate (3). Accordingly, the through hole (33) used for both the positioning and the injection of the resin (P) does not need to be large in order to facilitate the injection of the resin (P). As a result, the electronic apparatus (1) can be downsized while having the through hole (33) that can be used for both the positioning and the injection of the resin (P).

<2> In the electronic apparatus (1) of <1>, it is preferable that the attachment portion (22) includes a holding portion (23) that comes into contact with an end portion (35a) of the positioning jig (35) and holds the positioning jig (35), an inner space portion (24) that is provided on an inner side of the holding portion (23) and opens to a side (Z2 side in the Z direction) facing the substrate (3), and a communication portion (25) that communicates with an outer side from the inner space portion (24) in a direction along the substrate (3).

According to the present embodiment, at the time of manufacturing the electronic apparatus (1), when the resin (P) such as the potting material is injected from the through hole (33) provided in the substrate (3) into the partition portion (5), the resin (P) flows toward the attachment portion (22). In this case, if the attachment portion (22) is formed of a tubular body, since the resin (P) is temporarily retained inside the attachment portion (22), the resin (P) is difficult to smoothly spread over the entire partition portion (5), and a gas remains inside the attachment portion (22) to form a gap in the resin (P). Therefore, in the present embodiment, the attachment portion (22) includes the communication portion (25) that communicates with the outer side from the inner space portion (24) provided inside the holding portion (23). Accordingly, when the resin (P) is injected from the through hole (33) toward an inner side of the partition portion (5), the resin (P) flowing toward the attachment portion (22) can be easily diffused around the attachment portion (22) via the communication portion (25) in the partition portion (5). As a result, at the time of manufacturing the electronic apparatus (1), the partition portion (5) can be efficiently filled with the resin (P) injected from the through hole (33). In addition, since the attachment portion (22) includes the communication portion (25), when the resin (P) is injected, the gas in the inner space portion (24) is pushed out from the communication portion (25) to an outer side of the attachment portion (22), and thus the gas is unlikely to remain in the inner space portion (24). That is, in the electronic apparatus (1), generation of voids in the resin (P) is prevented.

<3> In the electronic apparatus (1) of <1>, it is preferable that the through hole (33) is provided so as to be located closer to a center of the partition portion (5) in any width direction (W1, W2) as viewed in the direction (Z direction) orthogonal to the substrate (3).

According to the present embodiment, since the through hole (33) provided in the substrate (3) is provided so as to be located closer to the center of the partition portion (5) in any width direction (W1, W2) as viewed in the direction orthogonal to the substrate (3), the resin (P) injected from the through hole (33) easily spreads throughout the partition portion (5). As a result, at the time of manufacturing the electronic apparatus (1), the partition portion (5) can be efficiently filled with the resin (P) injected from the through hole (33).

<4> In the electronic apparatus (1) of <1> to <3>, it is preferable that the substrate (3) has a plurality of the through holes (32, 33), and the attachment portion (22) is disposed so as to overlap at least one through hole (33) of the plurality of through holes (32, 33) as viewed in the direction (Z direction) orthogonal to the substrate (3).

According to the present embodiment, since the substrate (3) includes the plurality of through holes (32, 33), the number of positioning holes provided in the substrate (3) can be increased. Accordingly, the electronic apparatus (1) can easily position the substrate (3) with respect to the case (2). In addition, the attachment portions (22) are disposed so as to overlap two or more through holes (33) among the plurality of through holes (32, 33) as viewed in the direction (Z direction) orthogonal to the substrate (3), so that the partition portion (5) can be more quickly filled with the resin (P) injected from the through holes (33) into. In addition, when all of the plurality of through holes (33) are disposed so as to overlap the attachment portions (22) as viewed in the direction (Z direction) orthogonal to the substrate (3), a hole dedicated to positioning becomes unnecessary, and the substrate (3) can be downsized while securing a necessary area for pattern printing.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. An electronic apparatus comprising:
a substrate having a mounting surface on which an electronic component is disposed; and
a case disposed to face the mounting surface and including a partition portion configured to allow the electronic component to be accommodated, wherein
the substrate has a through hole,
the partition portion includes an attachment portion erected to a side of the substrate at a position overlapping the through hole as viewed in a direction orthogonal to the substrate, and
the partition portion is filled with a resin.

2. The electronic apparatus according to claim 1, wherein
the attachment portion includes
a holding portion that comes into contact with an end portion of a positioning jig and holds the positioning jig,
an inner space portion that is provided on an inner side of the holding portion and opens to a side facing the substrate, and
a communication portion that communicates with an outer side from the inner space portion in a direction along the substrate.

3. The electronic apparatus according to claim 1, wherein
the through hole is provided so as to be located closer to a center of the partition portion in any width direction as viewed in the direction orthogonal to the substrate.

4. The electronic apparatus according to claim 1, wherein
the substrate has a plurality of the through holes, and the attachment portion is disposed so as to overlap at least one of the plurality of through holes as viewed in the direction orthogonal to the substrate.

5. The electronic apparatus according to claim 2, wherein
the substrate has a plurality of the through holes, and the attachment portion is disposed so as to overlap at least one of the plurality of through holes as viewed in the direction orthogonal to the substrate.

6. The electronic apparatus according to claim 3, wherein
the substrate has a plurality of the through holes, and the attachment portion is disposed so as to overlap at least one of the plurality of through holes as viewed in the direction orthogonal to the substrate.
